(19) United States
(12) Patent Application Publication
(10) Pub. No.: US 2025/0266310 A1
(43) Pub. Date: Aug. 21, 2025

(54) ENCAPSULANT WITH LOW CTE AND LOW YOUNG MODULUS FOR LOW-STRESS ELECTRONIC PACKAGE

(71) Applicant: Infineon Technologies AG, Neubiberg (DE)

(72) Inventor: Alexander ROTH, Zeitlarn (DE)

(73) Assignee: Infineon Technologies AG, Neubiberg (DE)

(21) Appl. No.: 19/023,653

(22) Filed: Jan. 16, 2025

(30) Foreign Application Priority Data
Feb. 20, 2024 (DE) 10 2024 201 555.5

(51) Int. Cl. H01L 23/29; C08K 9/10

(52) U.S. Cl. CPC H01L 23/296; C08K 9/10; C08K 2201/005

(57) ABSTRACT

An encapsulant is disclosed. In one example, the encapsulant is an electronic package, wherein the encapsulant comprises an electrically insulating matrix material. Stress inhibiting filler particles, having a value of the coefficient of thermal expansion of not more than 6 ppm/K and a value of the Young modulus of not more than 4 GPa, are located in the matrix material.

### CROSS-REFERENCE TO RELATED APPLICATION

This Utility patent application claims priority to German Patent Application No. 10 2024 201 555.5 filed Feb. 20, 2024, which is incorporated herein by reference.

### BACKGROUND

### Technical Field

Various embodiments relate generally to an encapsulant and to a package.

### Description of the Related Art

A conventional package may comprise a semiconductor component mounted on a carrier such as a leadframe structure, may be electrically connected by a bond wire extending from the semiconductor component to the carrier, and may be molded using a mold compound as an encapsulant.

Power cycling is the testing of a package, device or module by switching it from the off to the on state repeatedly and according to a defined pattern in terms of time, peak allowable device temperature and electric current. It usually ends with the destruction of the package, device or module by rupture of key interfaces or connections of the package, device or module, due to coefficient of thermal expansion (CTE) induced material stress related fractures induced by the inhomogeneous temperate distribution in the package, device or module, i.e. material fatigue.

Power cycling performance of packages, devices and modules is becoming a key performance indicator. It would be desirable to obtain an appropriate power cycling behavior. More generally, electric reliability of such a package may be an issue.

### SUMMARY

There may be a need for a package with high electric reliability.

According to an exemplary embodiment, an encapsulant for an electronic package is provided, wherein the encapsulant comprises an electrically insulating matrix material, and stress inhibiting filler particles, having a value of the coefficient of thermal expansion of not more than 6 ppm/K and a value of the Young modulus of not more than 4 GPa, in the matrix material.

According to another exemplary embodiment, a package is provided which comprises a carrier, an electronic component mounted on the carrier, and an encapsulant at least partially encapsulating the electronic component and the carrier, wherein a value of the Young modulus of the encapsulant multiplied with an absolute value of a difference between values of the coefficient of thermal expansion of the encapsulant and of the electronic component is less than 372 GPa*ppm/K.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of an encapsulant according to an exemplary embodiment.

FIG. 2 illustrates a cross-sectional view of a package according to an exemplary embodiment.

FIG. 3 illustrates different types of stress inhibiting particles of an encapsulant according to an exemplary embodiment.

FIG. 4 illustrates a cross-sectional view of a package according to an exemplary embodiment.

FIG. 5 illustrates a cross-sectional view of a package according to another exemplary embodiment.

### DETAILED DESCRIPTION

There may be a need for a package with high electric reliability.

According to an exemplary embodiment, an encapsulant for an electronic package is provided, wherein the encapsulant comprises an electrically insulating matrix material, and stress inhibiting filler particles, having a value of the coefficient of thermal expansion of not more than 6 ppm/K and a value of the Young modulus of not more than 4 GPa, in the matrix material.

According to another exemplary embodiment, a package is provided which comprises a carrier, an electronic component mounted on the carrier, and an encapsulant at least partially encapsulating the electronic component and the carrier, wherein a value of the Young modulus of the encapsulant multiplied with an absolute value of a difference between values of the coefficient of thermal expansion of the encapsulant and of the electronic component is less than 372 GPa*ppm/K.

According to an exemplary embodiment, an encapsulant (for example a mold compound) for encapsulating an electronic package (in particular for encapsulating an electronic component mounted on a carrier) is provided. A matrix material may form the basis of the encapsulant and may be electrically insulating to thereby avoid undesired current flow between an exterior and an interior of the encapsulant (for example towards and/or from an encapsulated electronic component of a corresponding package). Advantageously, stress inhibiting filler particles (just to give an example, for instance porous zirconium tungstate particles) are inserted in the matrix which have a value of the coefficient of thermal expansion (CTE) of not more than 6 ppm/K and a value of the Young modulus of not more than 4 GPa (just to give an example, porous zirconium tungstate may have a CTE value of −7 ppm/K and a value of the Young modulus of 0.85 GPa). To put it shortly, the stress inhibiting filler particles added to the matrix material may be characterized by a soft low-stiffness property (as a consequence of the low value of the Young modulus) in combination with a very small positive or even a negative CTE value leading to an at least strongly limited thermal expansion of the encapsulant in the event of a temperature increase. Consequently, thermal stress may be strongly reduced while simultaneously giving the stress inhibiting filler particles and consequently the encapsulant as a whole a soft property. In combination with a matrix material of the encapsulant, for instance an epoxy resin, this may provide an encapsulant experiencing very limited stress so that an encapsulated electronic component (for instance a semiconductor chip which may be made for example substantially of silicon) of a package may be highly resistant against damage or failure during power cycling and during use even under harsh conditions. Consequently, an encapsulant for a package with high electric reliability may be obtained.

According to another exemplary embodiment, a package with encapsulated electronic component (such as a semiconductor chip, for example substantially made of silicon) is provided. Advantageously, the encapsulant is designed to have a value of the Young modulus which, multiplied with an absolute value of a difference between CTE values of the encapsulant and of the electronic component is less than 372 GPa*ppm/K. Descriptively speaking, the mentioned design rule corresponds to a sufficiently small stress-describing index reflecting a combined low-stiffness soft encapsulant with a simultaneously small CTE mismatch between the materials of the encapsulant and of the electronic component. In the event of pronounced temperature changes (for instance by heating the package) thermal expansion of the constituents of the package may create thermal stress. The package may be prone to damage in particular in the event of a strong difference of the CTE values of the individual constituents. Generally, resin of an encapsulant may have a significantly larger CTE value (for example more or even much more than 10 ppm/K) than semiconductor (in particular a silicon) material of the electronic component (for example 4-5 ppm/K). According to the above mentioned design rule, the encapsulant may be designed so that the CTE mismatch or difference of the CTE values between encapsulant and electronic component is sufficiently small so as to obtain a sufficiently low stress index allowing to suppress or prevent failure or damage during power cycling or during use under harsh conditions. To put it shortly, when the thermal stress is kept sufficiently small by a sufficiently low CTE mismatch (i.e. difference of CTE values of encapsulant and electronic component) and the encapsulant is designed soft enough to buffer thermal stress, the package may be reliably prevented against failure or damage. Thus, a sufficiently low stress-describing index as reflected by the above-described design rule may lead to high electric reliability. For example, the stress-describing index may be determined by measuring separately CTE values of encapsulant and electronic component, and the Young modulus value of the encapsulant.

### DESCRIPTION OF FURTHER EXEMPLARY EMBODIMENTS

In the following, further exemplary embodiments of the encapsulant and the package will be explained.

In the context of the present application, the term “encapsulant” may particularly denote a material, structure or member surrounding or intended for surrounding at least part of an electronic component and at least part of a carrier of a package. In this context, an encapsulant may provide mechanical protection and electrical insulation, and optionally a contribution to heat removal during operation. In particular, said encapsulant may be electrically insulating, for instance a mold compound. A mold compound may comprise a matrix of flowable and hardenable material, in particular a resin, optionally one or more additives, and optionally filler particles embedded therein. As an alternative to a mold compound (for example on the basis of epoxy resin), the encapsulant may also be a potting compound (for instance on the basis of an epoxy).

In the context of the present application, the term “encapsulant for electronic package” may particularly denote that the encapsulant is suitable and configured for encapsulating one or more constituents of an electronic package, in particular an electronic component and/or a carrier. This may require in particular a sufficient electric insulation of the encapsulant for preventing flow of electric current through the encapsulant. Furthermore, this may require a proper adhesion of the encapsulant with one or more constituents of the package (in particular an electronic component and/or a carrier), which may be accomplished by an appropriate matrix material and/or one or more appropriate additives of the encapsulant.

In the context of the present application, the term “electrically insulating matrix material” may in particular denote a material in which the stress inhibiting filler particles are embedded. The electrically insulating properties of the matrix material may be so pronounced that no noteworthy amount of electric current may flow through or along the encapsulant. Said matrix material may comprise a resin, in particular a polymer resin. For example, such a polymer resin may be an epoxy resin. For instance, the matrix material may be made of a curable material such as epoxy resin which may be hardened during an encapsulation process. Filler particles inside of said matrix material may fine-tune the package properties.

In the context of the present application, the term “filler particles” may particularly denote a (in particular powderous or granulate-type) substance filling out interior volumes in a surrounding medium such as a matrix.

In the context of the present application, the term “stress inhibiting filler particles” may in particular denote filler particles which are specifically configured for inhibiting stress, in particular thermal stress, in an interior of the encapsulant and/or between the encapsulant and an encapsulated electronic component. More specifically, the stress inhibiting filler particles may be provided with a sufficiently low value of the Young modulus and a sufficiently low value of the coefficient of thermal expansion so as to comply in combination with the above-mentioned design rules. In particular, stress inhibiting filler particles may be provided as nanoparticles or microparticles. Stress inhibiting filler particles may have identical dimensions or may be provided with a distribution of particle sizes. Such a particle size distribution may be preferred since it may allow for an improved filling of gaps in an interior of the encapsulant. The stress inhibiting filler particles can be modified, coated, and/or treated so as to improve the adhesion and/or the chemical binding to the surrounding matrix.

In the context of the present application, the term “coefficient of thermal expansion” (CTE) may in particular denote a parameter describing a rate at which a material expands with increase in temperature. For many materials, this CTE value is positive, while it can also be negative for certain other materials. In this context, thermal expansion may denote the tendency of matter to change its shape, area, volume, and density in response to a change in temperature. The relative expansion (also called strain) divided by the change in temperature may be denoted as the material's coefficient of thermal expansion. The value of the coefficient of thermal expansion may be given in ppm/K.

In the context of the present application, the term “Young modulus” may in particular denote a mechanical property of solid materials that measures a tensile or compressive stiffness when a force is applied lengthwise. The Young modulus may be defined as the ratio of the stress (i.e. force per unit area) applied to the object and the resulting axial strain (i.e. displacement or deformation) in the linear elastic region of the material. The value of the Young modulus may be given in GPa.

In the context of the present application, the term “package” may particularly denote an electronic device which may comprise one or more electronic components mounted on a (in particular partially or entirely electrically conductive) carrier. Said constituents of the package may be encapsulated at least partially by an encapsulant. Optionally, one or more electrically conductive connection elements (such as metallic pillars, bumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and optionally an electric connection function. A carrier may comprise or consist of a single part, multiple parts joined via encapsulation or other package components, or a subassembly of carriers. When the carrier forms part of a leadframe structure, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. Also at least part of the carrier may be encapsulated by the encapsulant, together with the electronic component.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

The parameter values (in particular of the coefficient of thermal expansion and of the Young modulus) mentioned in this application may be present in the temperature range of −40° C. to 250° C., in particular in the temperature range of −40° C. to 85° C., and more particularly in the temperature range of 0° C. to 70° C. Moreover, amounts of constituents of an encapsulant given in percent (%) in the present application may indicate weight percent.

In an embodiment, the stress inhibiting filler particles have a value of the Young modulus of not more than 1 GPa. Such very soft stress inhibiting filler particles may efficiently reduce stress in the encapsulant and the package. Even in the event of stress due to a certain CTE mismatch, such stress inhibiting filler particles may act as a mechanical buffer.

In an embodiment, the stress inhibiting filler particles have a value of the coefficient of thermal expansion of not more than 4 ppm/K. Since the mentioned CTE value is significantly lower than that of usable resin materials, in particular of usable epoxy resin materials, and may also be smaller than the CTE value of the electronic component (for instance made basically of silicon), such stress inhibiting filler particles may efficiently reduce the CTE mismatch and may therefore strongly suppress thermal stress.

In an embodiment, the stress inhibiting filler particles have a negative value of the coefficient of thermal expansion. Stress inhibiting filler particles having a negative CTE value may even contract upon heating and may therefore highly efficiently reduce the CTE mismatch by leading to a strong reduction of the encapsulant CTE being usually significantly larger than that of the electronic component.

In an embodiment, the stress inhibiting filler particles are porous. Porous stress inhibiting filler particles may comprise pores in its interior. Descriptively speaking, porous particles may have a lower CTE value and/or a lower value of the Young modulus than comparable continuously solid particles. It is believed that by making the stress inhibiting filler particles not only of a material having a low CTE value and a low value of the Young modulus but additionally creating porosity in said stress inhibiting filler particles may render them even softer. Thus, making stress inhibiting filler particles porous may further reduce their stiffness and may consequently lead to highly advantageous properties in terms of power cycling behavior.

In an embodiment, the stress inhibiting filler particles are closed porous particles. Closing porous stress inhibiting filler particles may be done by coating. When closing pores of the porous stress inhibiting filler particular towards their surroundings, the porous properties may be fully maintained even when inserting the porous stress inhibiting filler particles in a still flowable resin matrix of the encapsulant. Descriptively speaking, resin may then be prevented from flowing into and filling the pores which might reduce the degree of porosity.

Additionally or alternatively, it may also be possible to use open porous stress inhibiting filler particles, which may lead to a particularly simple manufacturing process.

In an embodiment, the porous stress inhibiting filler particles have a ratio between pore volume to whole particle volume in a range from 1% to 80%, in particular in a range from 1% to 40%. For example, said ratio may be in a range from 10% to 40%. In this context, the mentioned percentage of porosity (more precisely, the volume fraction of porosity) may be defined as the fraction of the volume of the stress inhibiting filler particles that is attributed to the pores. Preferably, the porous stress inhibiting filler particles may have a porosity in the range of 1% to 40% defined as the fraction of the apparent specific volume of the stress inhibiting filler particles that is attributed to the pores.

In an embodiment, the stress inhibiting filler particles have a functional coating. Descriptively speaking, coating (in particular porous) stress inhibiting filler particles may allow to maintain a classic interface between filler particles and a surrounding resin matrix. By coating an exterior surface of the stress inhibiting filler particles by a functional coating, the properties of the stress inhibiting filler particles may be adjusted or fine-tuned. For instance, the functional coating may be selected so as to enhance the stress inhibiting function provided by the stress inhibiting filler particles. For this purpose, it is for instance possible to apply a functional coating reducing the CTE mismatch between encapsulant and encapsulated electronic component and/or reducing the value of the Young modulus of the stress inhibiting filler particles.

In an embodiment, the functional coating comprises an insulator. Thus, the functional coating of the stress inhibiting filler particles may be electrically insulating, thereby enhancing dielectric properties of the encapsulant. This may, in turn, improve electric reliability of the package as a whole.

Additionally or alternatively, the functional coating comprises an adhesion promoter. In the context of the present application, the term “adhesion promoter” may particularly denote any material and/or measure enhancing adhesion between the stress inhibiting filler particles, on the one hand, and, on the other hand, other constituents of the encapsulant (for instance a matrix resin) and/or other constituents of the package (in particular the electronic component and/or the carrier). More specifically, such an adhesion promoter may act as an interface between the stress inhibiting filler particles and their environment to enhance adhesion in between.

In an embodiment, the adhesion promoter of the functional coating of the stress inhibiting filler particles comprises silane and/or a morphological adhesion promoter.

Hence, the adhesion promoter of the functional coating of the stress inhibiting filler particles may be a morphological adhesion promoter, i.e. an adhesion promoter having a morphological structure. In the context of the present application, the term “morphological structure” may particularly denote a structure having a topology and/or porous structure and/or being shaped in such a way so as to increase the connection surface to thereby promote adhesion. Moreover, the morphology of a morphological adhesion promoter may cause an advantageous mechanical interlocking between material of the morphological adhesion promoter and a surrounding of the stress inhibiting filler particles. In other words, a morphological structure promotes adhesion due to its shape, rather than only promoting adhesion due to its chemistry. However, it is also possible that a morphological structure is synergistically made of material which, in view of its intrinsic properties, promotes adhesion additionally to the shape. In particular, a morphological adhesion promoter may be an inorganic porous material. For instance, the presence of a morphological structure between the stress inhibiting filler particles and their environment may additionally promote the interconnection between the stress inhibiting filler particles and the environment so as to further improve reliability. Highly advantageously, the adhesion promoter may promote adhesion at least partially as a result of its morphology. Thus, a specific shaping and in particular increase of the interior surface of the adhesion promoter may enhance adhesion between the stress inhibiting filler particles and their environment, mediated by the morphological adhesion promoter.

In an embodiment, the morphological adhesion promoter comprises at least one of the group consisting of a metallic structure, an alloy structure, a chromium structure, a vanadium structure, a molybdenum structure, a zinc structure, a manganese structure, a cobalt structure, a nickel structure, a copper structure, a flame deposited structure, a roughened metal structure (in particular a roughened copper structure or a roughened aluminum oxide structure), and any oxide, nitride, carbide, and selenide of any of said structures. All structures may comprise or consist of these metals and/or the alloys thereof. In addition, these structures may comprise or consist of these metals and their alloy-oxides. In particular, single oxides and mixed oxides are possible in different embodiments. However, other materials and structures may be used for the morphological adhesion promoter as well. The above-mentioned flame deposited structure may comprise or consist of silicon dioxide, any titanium oxide (such as for instance TiO₂, TiO, TiₓO_{y}), etc. Any organometallic precursor can be used that can be burned in a mixture with a burning gas such as propane or butane and form the specific metal oxide. In particular, a morphological adhesion promoter may be formed using Atomic Layer Deposition (ALD), Chemical Vapor Deposition (CVD), etc.

In another embodiment, the adhesion promoter of the stress inhibiting filler particles may be an organic adhesion promoter, such as silane. Such an organic adhesion promoter may promote adhesion in view of its chemical properties.

In an embodiment, the stress inhibiting filler particles comprise at least one material of zirconium tungstate, porous silica, boron-silicate glass, β-eucryptite, α-ZrW₂O₈, β-ZrW₂O₈, Cd(CN)₂, ReO₃, (HfMg)(WO₄)₃, Sm_{2.75}C₆₀, Bi_{0.95}La_{0.05}NiO₃, Invar (Fe-36Ni), Invar (Fe₃Pt), Tm₂Fe₁₆Cr, copper oxide nano particles, and Mn₃Cu_{0.53}Ge_{0.47}N. Particularly preferred may be zirconium tungstate, α-ZrW₂O₈, ReO₃, (HfMg)(WO₄)₃, Invar (Fe-36Ni), Invar (Fe₃Pt), and copper oxide nano particles. These materials, as such or in a porous variant and/or with an appropriate coating, may meet the requirements of low or even negative CTE value, and may also have a low value of the Young modulus, in particular when embodied porous.

In an embodiment, the stress inhibiting filler particles have a size below 100 μm, in particular in a range from 1 μm to 30 μm. With such sizes, the stress inhibiting filler particles are compatible with homogeneous properties of the encapsulant.

In an embodiment, the stress inhibiting filler particles are round. However, the stress inhibiting filler particles may also have other geometries. For instance, the shape of the stress inhibiting filler particles may be randomly, spherical, cuboid-like, flake-like, and film-like.

In an embodiment, the encapsulant additionally comprises functional filler particles providing at least one additional function to the encapsulant. For instance, the at least one additional function provided by the functional filler particles may be an increase of thermal conductivity of the encapsulant, an increase of hardness of the encapsulant, and/or a reduction of mismatch of the coefficient of thermal expansion between the encapsulant and a semiconductor material, in particular silicon or silicon carbide. Thus, the encapsulant may further comprise functional filler particles in the matrix material, i.e. at least one second type of filler particles in addition to the stress inhibiting filler particles. By the selection of the functional filler particles, the physical and/or chemical properties of the encapsulant can be adjusted. Such properties may include the coefficient of thermal expansion, the thermal conductivity, the dielectric properties, etc. The functional filler particles may thus be added so as to fine tune the physical, chemical, etc., properties of the encapsulant. For instance, the functional filler particles may increase thermal conductivity of the encapsulant so as to efficiently remove heat out of an interior of the package (such heat may be generated by a semiconductor component, for instance when embodied as power semiconductor chip). It is also possible that the functional filler particles provide an improved dielectric decoupling between such a semiconductor component and the surrounding of the package.

In an embodiment, functional filler particles are selected from a group consisting of aluminium hydroxide, magnesium hydroxide, zirconium dioxide, calcium carbonate, calcium silicate, talc, clay, carbon fiber, glass fiber and mixtures thereof. Other functional filler materials are however possible depending on the demands of a certain application. Functional filler particles (for example Al₂O₃, Si₃N₄, BN, AlN, diamond, etc.), for instance for improving thermal conductivity may be used as well. In particular, organic particles may be used as functional fillers (for instance, functional fillers can also comprise or consist of polymers or polymer mixtures, such as: epoxies, polyethylene, polypropylene, etc.).

In an embodiment, an overall amount of filler particles (in particular stress inhibiting filler particles, and optionally in addition one or more additional types of functional filler particles) of the encapsulant, in relation to the encapsulant as a whole, may be in a range from 60 weight percent to 95 weight percent, in particular in a range from 70 weight percent to 90 weight percent. Such a filler content in relation to the matrix material (in particular resin material) may allow to achieve overall desired properties of the encapsulant as a whole.

In an embodiment, the matrix material comprises an epoxy resin, silicone, a bismaleimide and/or an imide. Epoxy resin may be an appropriate matrix material for an epoxy mold compound (EMC). Silicone may form the basis of a gel-type encapsulant for potting.

In an embodiment, the encapsulant is configured as a mold compound, in particular as an epoxy-based mold compound. Thus, different mold compound types may be used, such as silicone mold compound, bismaleimide mold compound, imide mold compound, etc. Molding may denote a manufacturing process of shaping liquid or pliable raw material using a rigid tool called a mold. Hence, encapsulation of the one or more electronic components, in particular semiconductor components, of the semiconductor package may be accomplished by molding. Consequently, the encapsulant may comprise a curable matrix (for instance on the basis of epoxy resin) with filler particles therein.

In an embodiment, the encapsulant is configured as a potting compound, in particular as an epoxy-based potting. In particular, potting may denote a process of filling an electronic assembly with a solid or gelatinous compound, for example for high voltage assemblies. This may suppress or exclude gaseous phenomena such as corona discharge, may be done for resistance to shock and vibration, and/or may be executed for the exclusion of water, moisture, etc.

In an embodiment, the encapsulant of the package comprises an electrically insulating matrix material, and stress inhibiting filler particles, for example having a value of the coefficient of thermal expansion of not more than 6 ppm/K and/or a value of the Young modulus of not more than 4 GPa, in the matrix material. Generally, the encapsulant of the package may be configured according to any of the above mentioned embodiments.

In preferred embodiments of the package, the value of the Young modulus of the encapsulant multiplied with the absolute value of the difference between the values of the coefficient of thermal expansion of the encapsulant and of the electronic component is less than 200 GPa*ppm/K, more preferably less than 100 GPa*ppm/K. Thus, the Young modulus and/or the CTE values of the constituents of the encapsulant may be adjusted so as to obtain the mentioned stress-indicating index values, which may improve the power cycling properties of encapsulant and package over conventional approaches in an even stronger way. Table 2 gives an example how this can be achieved. A sufficiently large amount of stress inhibiting filler particles, the provision of porous stress inhibiting filler particles with a sufficiently large porosity percentage, and a selection of stress inhibiting filler particles with sufficiently low (preferably negative) CTE value and/or low value of the Young modulus are measures which can be taken to achieve such very small stress-describing index values.

In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user convenient.

In an embodiment, the electronic component is a semiconductor power chip. Thus, the semiconductor component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the package comprises a plurality of electronic components, in particular semiconductor components, encapsulated by the package encapsulant. Thus, the package may comprise one or more semiconductor components (for instance at least one passive component, such as a capacitor, and at least one active component).

In an embodiment, the electronic component is a semiconductor chip, for example comprising silicon. In particular when the electronic component is embodied as a semiconductor chip made predominantly or silicon or silicon carbide material, the CTE mismatch with epoxy-based encapsulant material may be very pronounced. Thus, in particular under such circumstances, the provision of stress inhibiting filler particles and/or an encapsulant with sufficiently low stress-describing index value may be of utmost advantage.

For example, the stress inhibiting filler particles may be subjected to a coating and/or surface treatment process before mixing the stress inhibiting filler particles with the matrix material.

In particular, it may be possible to mix the stress inhibiting filler particles with the matrix material before or after adding additional filler particles and/or at least one further additive.

As substrate or wafer forming the basis of the electronic component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Power cycling performance of packages may be critical. A usual failure mode may be rupture of key interfaces. A factor which promotes power cycling failure may be inhomogeneous temperate distribution in the device, due to CTE induced material stress related fractures, i.e. material fatigue. Thus, it may be desirable to have an encapsulation with a controlled or tunable low Young modulus. Also, a controlled CTE delta at a critical interface to a die may be helpful.

It has been found that the behavior of a package during power cycling, as explained above, is determined by multiple material properties of the encapsulation, among them the values of CTE and the Young modulus. Both factors may be temperature dependent and not discrete points.

It would be desirable to have an encapsulation with a controlled or tunable low Young modulus to enable longer power cycling lifetimes and/or tailor the encapsulation to a desired power cycling regime (for example dependent on a temperature difference or range or on or upper temperature limit in the power cycling).

Issues with conventional mold compounds are that they are loaded with filler particles (for instance alumina particles), which have very high values of the Young modulus, and are consequently extremely stiff, and induce high stress during power cycling. At high filler loadings, this may result in mold compounds with high compound value of the Young modulus, for example significantly more than 20 GPa.

According to an exemplary embodiment, an encapsulant (such as a mold compound) for an electronic package (in particular for a semiconductor package comprising silicon) may add stress inhibiting filler particles (like porous zirconium tungstate) in a matrix with resin (for instance epoxy resin, which may also comprise functional filler particles, such as alumina). Advantageously, said stress inhibiting filler particles may be selected to have a CTE value of not more than 6 ppm/K and a value of the Young modulus of not more than 4 GPa. As a result, a softer encapsulant may be obtained which is better able to buffer stress. Such a low-stiffness characteristics may be synergistically combined with a low CTE value limiting thermal expansion and thus thermal stress. As a result, an encapsulant may be provided which does not cause excessive stress when encapsulating the electronic component, such as a semiconductor component (for instance comprising silicon). Consequently, the risk of damage or failure during power cycling may be reduced, and improved electric reliability may be obtained.

According to another exemplary embodiment (which may or may not be combined with the previously described embodiment), an electronic component (such as a semiconductor chip, for instance comprising silicon) may be encapsulated by an encapsulant for forming a package. Beneficially, the product of the net, averaged or effective value of the Young modulus of the encapsulant and an absolute value of a difference between the net, averaged or effective CTE values of the encapsulant and of the electronic component may be below 372 GPa*ppm/K. The afore-mentioned limited parameter range may be indicative of an acceptably low amount of stress, as it may reflect softness of the encapsulant in combination with a sufficiently small CTE mismatch between encapsulant and encapsulated electronic component. In view of the above mentioned design rule of the stress-describing index being below 372 GPa*ppm/K, stress may be reduced significantly over conventional approaches, for instance by at least 30%. A correspondingly manufactured package may thus be protected against failure or damage during power cycling.

A model for stress in a package comprising an encapsulant (such as a mold compound) encapsulating an electronic component (such as a silicon die) may be based on a stress index (SI) reflecting combined effects of CTE values (CTE), temperature (T), glass transition temperature (Tg) of the encapsulant and Young modulus (E). Such a model may be based on the following equation:

$$SI = ( C T {E}_{1} - CT {E}_{x} ) ( T - {T}_{g} ) {E}_{1} + ( C T {E}_{2} - CT {E}_{x} ) ( T - 175 ) {E}_{2}$$

In said equation, index 1 (corresponding to room temperature) and index 2 (corresponding to high temperature) relate to the mold compound, index x relates to the silicon die.

To estimate the stress in power cycling from semiconductor to encapsulation in a further simplified model, the scenario may be modelled as follows for the regime under Tg: Isothermal conditions are assumed directly near the semiconductor, i.e. it may be assumed that the epoxy mold compound and the semiconductor die have the same temperature. When heating up, semiconductor die and encapsulation may experience CTE driven length and volume changes. As semiconductor die and encapsulation are solidly attached, this may induce stress at the interface, according to the Hooke law.

Consequently, the stress on the semiconductor die top side may be proportional to:

Stress˜(CTE_{encapsulation}−CTE_{die})E_{encapsulation}

According to an exemplary embodiment, the design of the constituents of the encapsulant may be such that the stress-describing index is sufficiently small. As will be described below referring to Example 1, a power cycling-resistant package according to an exemplary embodiment may use an epoxy mold compound with a stress index (ΔCTE×E) less than 70% of that of conventional approaches. In particular, this may involve the provision of stress inhibiting filler particles with sufficiently low value of the Young modulus and a sufficiently low value of the CTE.

According to an exemplary embodiments, a tailorable epoxy mold compound with low CTE and low Young modulus may be provided, leading to reduced package stress under power cycling.

According to exemplary embodiments, it may be possible to create an epoxy mold compound with negative thermal expansion (NTE) particles, i.e. stress inhibiting filler particles having a negative value of the coefficient of thermal expansion (CTE). This may allow to improve power cycling performance by a partial admix of stress inhibiting filler particles having a low CTE or negative CTE and a low Young modulus in an epoxy mold compound. Preferably, porous stress inhibiting filler particles can be used in conjunction to further lower Young modulus and CTE. For example, zirconium tungstate filler particles may be coated or treated prior to admix. For example, the stress inhibiting filler particles may be coated with an adhesion promoter or an isolation compound different from the epoxy compound. For instance, the stress inhibiting filler particles are admixed during epoxy mold compound production, for example before or after adding other fillers (such as functional filler particles) and/or other components or additives of mold compound formulation.

According to exemplary embodiments, it may be possible to partially admix stress inhibiting filler particles with low CTE and low Young modulus, in particular with negative CTE, and/or in conjunction with (preferably closed) porous particles to further lower the Young modulus and/or the CTE. One preferred example for a material of the stress inhibiting filler particles is zirconium tungstate, preferably porous and/or coated. One other embodiment of the stress inhibiting filler particles is to use porous silica particles.

In different embodiments, the stress inhibiting filler particles may be of any shape, but preferably round. They may have particle sizes below 100 μm, for example in a range from 1 μm to 30 μm. For instance, the stress inhibiting filler particles may be porous, for instance in the range of up to 80%, but preferably in a range of 1% to 40%. In different embodiments, open porous or closed porous stress inhibiting filler particles may be used, but preferably closed porous ones. For example, the stress inhibiting filler particles of the encapsulant may have a compound CTE of less than 4 ppm/K for instance in the range of 0° C. to 150° C. The stress inhibiting filler particles may have a Young modulus less than 1 GPa. They may optionally be coated or treated prior to admixture, for example with an adhesion promotor (for example silanes, or a morphological adhesion promoter), and/or an isolation compound different from the epoxy compound.

Alternatively, properly treated glass (or silica) may be used, preferably properly treated boron-silicate glasses, as stress inhibiting filler particles.

In an embodiment, the stress inhibiting filler particles may be admixed during epoxy mold compound production, before or after adding the other fillers and component substances of the mold compound formulation.

According to an embodiment, stress inhibiting filler particle loading may be in a range up to 40% volume fraction, but preferably in a range of 1% to 15%. For example, a weight percentage of the stress inhibiting filler particles, in relation to the entire weight of the encapsulant, may be below 40%, preferably in a range from 1% to 15%.

### Example 1

In the following, a justification for the upper limit of 372 GPa*ppm/K for the product of the value of the Young modulus of the encapsulant multiplied with the absolute value of the difference between values of the coefficient of thermal expansion of the encapsulant and of the electronic component will be given. For example, an epoxy mold compound (EMC), see the first and third parameter rows of Table 1 and the first parameter row of Table 2, with 20% resin and 80% functional filler particles made of silica may have a value of the Young modulus of 48.4 GPa and may have a coefficient of thermal expansion of 16 ppm/K. An electronic component embodied as silicon die may have a coefficient of thermal expansion of 5 ppm/K. Thus, a product of the value of the Young modulus of the encapsulant multiplied with the absolute value of the difference between CTE values of the encapsulant and of the electronic component may be equal to 48.4 GPa*(16−5) ppm/K=532 GPa*ppm/K. Per hybrid rule of mixtures, the following considerations apply: 70% of this product may be 372 GPa*ppm/K. This may roughly correspond to an admixture of 15% stress inhibiting filler particles embodied as 40% porous zirconium tungstate in an embodiment, as can be taken from the first to third parameter rows of Table 1 and the second parameter row of Table 2.

TABLE 1
constituents of an encapsulant

| Material | Young modulus [GPa] | CTE [ppm/K] |
|---|---|---|
| Matrix: resin | 2 | 60 |
| Stress inhibiting filler particles: | 0.85 | −7 |
| 40% porous zirconium tungstate | | |
| Functional filler particles: silica | 60 | 5 |

TABLE 2
parameter values for different amounts
of constituents of an encapsulant

| | Porous | | Young | | stress- |
|---|---|---|---|---|---|
| | zirconium | | modulus | CTE | describing |
| Resin | tungstate | Silica | encapsulant | encapsulant | index |
| [%] | [%] | [%] | [GPa] | [ppm/K] | [GPa*ppm/K] |
| 20 | 0 | 80 | 48.4 | 16.0 | 532.4 |
| 20 | 15 | 65 | 39.5 | 14.2 | 363.7 |
| 20 | 25 | 55 | 33.6 | 13.0 | 268.9 |
| 20 | 45 | 35 | 21.8 | 10.6 | 122.0 |
| 20 | 55 | 25 | 15.9 | 9.4 | 69.8 |
| 20 | 65 | 15 | 10.0 | 8.2 | 31.8 |

More precisely, based on the values of the Young modulus and the CTE for the individual constituents of the encapsulant according to Table 1, averaged values of the Young modulus and of the CTE for the encapsulant may be calculated, see Table 2.

For instance, what concerns estimation of an average value of the Young modulus, an averaged or effective value of the Young modulus (E_{composite}) for a composite, such as an encapsulant comprising multiple constituents, each having a respective value of the Young modulus (E_{constituent}), can be estimated based on the rule of mixtures (VF_{constituent} may denote the volume fraction of the respective constituent of the composite):

E_{composite}=ΣE_{constituent}VF_{constituent}

For different percentages of the stress inhibiting filler particles, the above explained stress-describing index may be regulated or adjusted. Referring to the first parameter row of Table 2, a scenario without stress inhibiting filler particles is shown, i.e. only matrix resin and functional filler particles of silica are present. The second parameter row of Table 2 indicates that the addition of 15% stress inhibiting filler particles in form of 40% porous zirconium tungstate improves the stress-describing index by reducing it to approximately 70% of the conventional value of the first parameter row of Table 2. Still referring to the first and second parameter rows of Table 2, the amount of functional filler particles is reduced by the amount of added stress inhibiting filler particles in the shown Example 1. As can be taken from the subsequent parameter rows of Table 2, larger amounts of stress inhibiting filler particles may further improve the stress-describing index. The described Example 1 may allow to provide a highly appropriate encapsulant material by adjusting both CTE values and values of the Young modulus thanks to the addition of the stress inhibiting filler particles. All parameter rows of Table 2 relate to a constant overall filler content of 80%, which may be advantageous in terms of the overall properties of the encapsulant. However, it may be also possible to adapt the overall filler content when adjusting CTE and/or Young modulus for improving properties in terms of power cycling. As can be taken from Table 2, the stress-describing index may be lowered by at least one order of magnitude due to the addition of the stress inhibiting filler particles.

### Example 2

The following example differs from the previous example in that 40% porous silicon oxide is used as stress inhibiting filler particles (rather than 40% porous zirconium tungstate as in the previous Example 1) in the encapsulant, see Table 3.

TABLE 3
constituents of an encapsulant

| Material | Young modulus [GPa] | CTE [ppm/K] |
|---|---|---|
| Matrix: resin | 2 | 60 |
| Stress inhibiting filler particles: | 30 | 5 |
| 40% porous silicon oxide | | |
| Functional filler particles: silica | 60 | 5 |

TABLE 4
parameter values for different amounts
of constituents of an encapsulant

| | Porous | | Young | | stress- |
|---|---|---|---|---|---|
| | silicon | | modulus | CTE | describing |
| Resin | oxide | Silica | encapsulant | encapsulant | index |
| [%] | [%] | [%] | [GPa] | [ppm/K] | [GPa*ppm/K] |
| 20 | 0 | 80 | 48.4 | 16.0 | 532.4 |
| 20 | 55 | 25 | 31.9 | 16.0 | 350.9 |
| 20 | 65 | 15 | 28.9 | 16.0 | 317.9 |

As can be taken from Table 4 (showing corresponding information as above Table 2), adding 55% of 40% porous silicon oxide to the encapsulant will allow to meet the target value for the stress-describing index of 372 GPa*ppm/K. Adding 65% of 40% porous silicon oxide to the encapsulant will allow to obtain even better values for the stress-describing index. As can be taken from Table 4, the addition of the stress inhibiting filler particles may reduce the stress-describing index by approximately 40%.

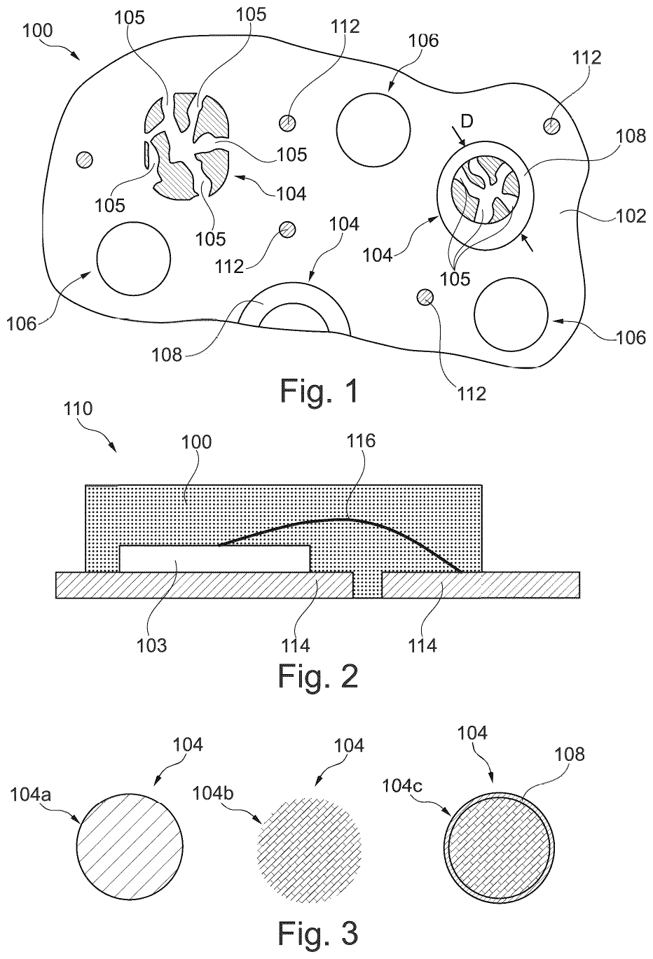

FIG. 1 illustrates an encapsulant 100 according to an exemplary embodiment.

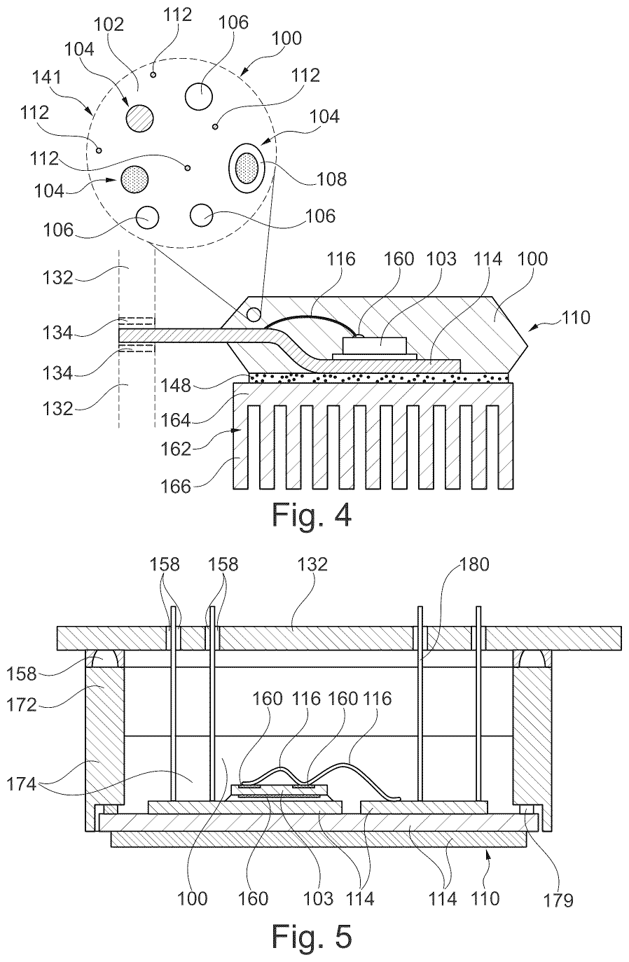

The schematically illustrated encapsulant 100 is configured for encapsulating an electronic package 110, such as the one shown in FIG. 2, FIG. 4 or FIG. 5.

As shown, the encapsulant 100 comprises an electrically insulating matrix material 102. For a mold compound-type encapsulant 100 as used for the package 110 of FIG. 2 or FIG. 4, the matrix material 102 may comprise an epoxy resin. For a potting-type encapsulant 100 as used for the package 110 of FIG. 5, the matrix material 102 may comprise silicone.

Moreover, the encapsulant 100 may comprise stress inhibiting filler particles 104 which may have a value of the coefficient of thermal expansion of not more than 6 ppm/K, preferably not more than 4 ppm/K. They may even have a negative coefficient of thermal expansion. As a result, the overall, averaged or net CTE value of the encapsulant 100 may be strongly reduced by the presence of the stress inhibiting filler particles 104. This may reduce a CTE mismatch in a package 110 with respect to silicon material of an encapsulated electronic component 103 and may therefore reduce thermal stress.

Moreover, a value of the Young modulus of the stress inhibiting filler particles 104 may be not more than 4 GPa, preferably not more than 1 GPa. This may give the encapsulant 100 a soft property and thus the capability of mechanically buffering thermal stress. For example, the stress inhibiting filler particles 104 may comprise zirconium tungstate, porous silica, and/or coated boron-silicate glass.

As shown, at least some of the stress inhibiting filler particles 104 may be porous, i.e. may comprise pores 105. This may further reduce stiffness of the stress inhibiting filler particles 104 and may further enhance the capability of the stress inhibiting filler particles 104 to buffer stress. At least a part of the porous stress inhibiting filler particles 104 may be closed porous particles having a coating 108. However, it is also possible that at least a part of the porous stress inhibiting filler particles 104 may be open porous particles having no coating 108. Porous stress inhibiting filler particles 104 with coating 108 may be preferred, since this may provide a defined interface to a surrounding resin of matrix material 102 and may keep the pores 105 unfilled or void. Preferably, the porous stress inhibiting filler particles 104 have a ratio between pore volume to whole particle volume in a range from 1% to 40%.

At least part of porous and/or non-porous stress inhibiting filler particles 104 may have a functional coating 108 which may comprise an adhesion promoter (for instance silane and/or a morphological adhesion promoter) and/or an insulator.

As shown, at least part of the preferably (but not necessarily) round stress inhibiting filler particles 104 may have a maximum diameter or size D preferably in a range from 1 μm to 30 μm.

A weight percentage of the stress inhibiting filler particles 104, in relation to an overall weight of the encapsulant 100, may be for instance up to 70%, preferably in a range from 10% to 40%.

In addition to the stress inhibiting filler particles 104, the encapsulant 100 may comprise functional filler particles 106 for providing at least one additional function to the encapsulant 100. This at least one additional function may be for instance an increase of thermal conductivity of the encapsulant 100. For example, the functional filler particles 106 may comprise aluminum nitride. All functional filler particles 106 may be of the same type. Alternatively, different sub-types of functional filler particles 106 may be used, for instance a mixture of different materials.

A weight percentage of the stress inhibiting filler particles 104 plus the functional filler particles 106, in relation to an overall weight of the encapsulant 100, may be for instance up to 95%, preferably in a range from 70% to 90%.

Apart from this, one or a plurality of further additives 112 (shown schematically in FIG. 1) may be added to the encapsulant 100 for further adjusting its physical properties and for providing a dedicated functionality. For example, the additives 112 may comprise a colorant, a voltage stabilizer, an antioxidant, an ultraviolet (UV) absorber, an adhesion promoter, etc.

FIG. 2 illustrates a cross-sectional view of a molded package 110, which may be a power package, according to an exemplary embodiment.

The illustrated package 110 comprises a carrier 114, which may for instance be a leadframe structure, for instance made of copper. An electronic component 103 may be mounted on the carrier 114. For instance, the electronic component 103 may be a semiconductor die, for instance manufactured in silicon technology or silicon carbide technology. For example, the electronic component 103 may be a semiconductor power chip. An electrically conductive connection element 116, for example a bond wire, may electrically couple the electronic component 103 with the carrier 114. An encapsulant 100, for example the encapsulant 100 of FIG. 1, may encapsulate the electronic component 103, the electrically conductive connection element 116, and part of the carrier 114.

Advantageously, the encapsulant 100 of FIG. 2 may be manufactured in accordance with a design rule according to which a value of the Young modulus of the encapsulant 100 multiplied with an absolute value of a difference between values of the coefficient of thermal expansion of the encapsulant 100 and of the electronic component 103 is less than 372 GPa*ppm/K, and preferably is less than 200 GPa*ppm/K. This may allow to significantly reduce a stress-describing index, for instance in a way as described above for Example 1 or Example 2. For instance, the encapsulant 100 may be constructed as described above referring to FIG. 1.

FIG. 3 illustrates different types of stress inhibiting filler particles 104 of an encapsulant 100 according to an exemplary embodiment.

A stress inhibiting filler particle 104a of a first type may be a continuously solid particle, for instance made of a material having a negative thermal expansion (NTE), i.e. having a negative value of the CTE.

A stress inhibiting filler particle 104b of a second type may be a porous particle, in particular a porous NTE particle.

A stress inhibiting filler particle 104c of a third type may be a coated particle, in particular a coated porous NTE particle.

Any of the three shown and/or other types of stress inhibiting filler particles 104a, 104b, 104c, 104 may be used alone, or in combination.

FIG. 4 illustrates a cross-sectional view of a molded package 110 according to an exemplary embodiment.

The semiconductor package 110 is mounted on a mounting structure 132, here embodied as printed circuit board (PCB).

The mounting structure 132 comprises an electric contact 134 embodied as a plating in a through hole of the mounting structure 132. When the semiconductor package 110 is mounted on the mounting structure 132, a semiconductor component 103 of the semiconductor package 110 is electrically connected to the electric contact 134 via an electrically conductive carrier 114, here embodied as a leadframe made of copper.

The semiconductor package 110 thus comprises the electrically conductive carrier 114, the semiconductor component 103 (which is here embodied as a power semiconductor chip) mounted on the carrier 114, and an encapsulant 100 encapsulating part of the carrier 114 and the semiconductor component 103.

As can be taken from FIG. 4, a pad 160 on an upper main surface of the semiconductor component 103 is electrically coupled to the carrier 114 via a bond wire as electrically conductive connection element 116. Alternatively, a clip may be used as electrically conductive connection element 116 (not shown).

In particular, the carrier 114 may comprise different leads, that are going out of the encapsulant 110 of the package 110. The backside of the semiconductor component 103 (such as a die) is connected to one part of the carrier 114, while the electrically conductive connection element 116 (such as a bond wire) is not connected to the same lead. Instead, each lead may be separately connected to the carrier 114 at different contact holes.

During operation of the power semiconductor package 110, the power semiconductor chip in form of the semiconductor component 103 generates a considerable amount of heat. At the same time, it shall be ensured that any undesired current flow between a bottom surface of the semiconductor package 110 and an environment is reliably avoided.

For ensuring electrical insulation of the semiconductor component 103 and removing heat from an interior of the semiconductor component 103 towards an environment, an electrically insulating and thermally conductive interface structure 148 may be provided which covers an exposed surface portion of the carrier 114 and a connected surface portion of the encapsulant 100 at the bottom of the semiconductor package 110. The electrically insulating property of the interface structure 148 prevents undesired current flow even in the presence of high voltages between an interior and an exterior of the semiconductor package 110. The thermally conductive property of the interface structure 148 promotes a removal of heat from the semiconductor component 103, via the electrically conductive carrier 114 (for instance of thermally conductive copper), through the interface structure 148 and towards a heat dissipation body 162. The heat dissipation body 162, which may be made of a highly thermally conductive material such as copper or aluminum, has a base body 164 directly connected to the interface structure 148 and has a plurality of cooling fins 166 extending from the base body 164 and in parallel to one another so as to remove the heat towards the environment.

Construction and function of encapsulant 100 can be for instance as illustrated in and described referring to FIG. 1, see detail 141. The illustrated semiconductor package encapsulant 100 encapsulates the semiconductor component 103 with its metallic pad 160, leadframe-type metallic chip carrier 114, and bond wire-type electrically conductive connection element 116 partially or entirely.

FIG. 5 illustrates a cross-sectional view of a semiconductor package 110 with a semiconductor component 103 encapsulated by potting according to another exemplary embodiment. Thus, FIG. 5 illustrates a semiconductor package encapsulant 100 embodied as potting compound. The semiconductor package 110 of FIG. 5 can be a power package.

The shown semiconductor package 110 is mounted with a mounting structure 132 being embodied as printed circuit board (PCB). Semiconductor package 110 is mounted at its mounting interface on the mounting structure 132 with a sealing 158 in between. Preferably, the gas flow-inhibiting sealing 158 may establish a gas flow-tight connection between semiconductor package 110 and mounting structure 132.

The semiconductor package 110 comprises a semiconductor component 103, such as a power semiconductor chip, for instance comprising a field effect transistor (FET). Semiconductor component 103 has metallic pads 160.

An enclosure 174 encloses the semiconductor component 103 and defines a module interface at which the semiconductor package 110 is to be mounted on the mounting structure 132. In the shown embodiment, the enclosure 174 is composed of two parts. A first or interior part of the enclosure 174 is embodied as a soft encapsulant 100 (for instance made of epoxy and comprising a stress inhibiting filler particles 104, not shown in FIG. 5) which directly encapsulates the semiconductor component 103 with physical contact, for instance is applied by potting. A second or exterior part of the enclosure 174 is embodied as a rigid casing or housing 172 which may be made of plastic and accommodates the semiconductor component 103 and the soft encapsulant 100.

Furthermore, vertically extending electrically conductive needles 180 may be provided which electrically couple the semiconductor component 103 and the carrier 114 with an exterior of the semiconductor package 110, more precisely with the mounting structure 132. The needles 180 may also extend through the mounting structure 132. More precisely, bottom ends (according to FIG. 5) of the needles 180 may be connected at an upper main surface of the carrier 114. Furthermore, top ends (according to FIG. 5) of the needles 180 may be guided through the mounting structure 132 and may even protrude beyond the upper side of the mounting structure 132.

As shown as well in FIG. 5, the semiconductor package 110 comprises carrier 114 carrying the semiconductor component 103. The semiconductor component 103 may be soldered on the carrier 114. In the shown embodiment, the carrier 114 comprises a central thermally conductive and electrically insulating plate (for instance made of a ceramic) covered on both opposing main surfaces thereof with a respective electrically conductive layer (such as a continuous or patterned copper or aluminium layer). For instance, the carrier 114 may be a Direct Copper Bonding (DCB) substrate or a Direct Aluminium Bonding (DAB) substrate. It is also possible to embody the carrier 114 as Active Metal Brazing (AMB) substrate. The semiconductor component 103 is mounted on the top-sided electrically conductive layer. The bottom-sided electrically conductive layer may be connected to a heat sink (not shown) for promoting heat removal out of the semiconductor package 110 during operation thereof.

Thus, the outer layer of the carrier 114 is configured for mounting a heat sink (not shown) thereon in order to efficiently remove heat out of the semiconductor package 110, which is generated by semiconductor component 103 mounted on the interior layer of the carrier 114. Said semiconductor component 103 may, for instance, be a power semiconductor chip. Electric connection of the semiconductor component 103 can be accomplished by the carrier 114 (in particular by the inner electrically conductive layer thereof) and by electrically conductive connection elements 116 connecting the carrier 114 with the pads 160 on an upper main surface of the semiconductor component 103. Said electrically conductive connection elements 116 are here embodied as bond wires, but may alternatively be bond ribbons or clips.

As shown as well, the semiconductor component 103 mounted on the carrier 114 is enclosed within the enclosure 174, which is composed of soft encapsulant 100 and wall of housing 172.

The semiconductor package 110 can further comprise a further gas flow-inhibiting sealing 179 between the carrier 114 and the housing 172 of the enclosure 174.

The electrically conductive needles 180 extend from the carrier 114 through the encapsulant 100 and through sealing 158 at the module interface at which the semiconductor package 110 faces mounting structure 132. For instance, the semiconductor package 110 and the mounting structure 132 may be connected by screwing, soldering, sintering, gluing and/or mechanically pressing.

By embodying the potting-type encapsulant 100 in a corresponding way as described above referring to FIG. 1 (preferably based on epoxy resin as matrix 102), a high electric reliability also in terms of power cycling may be achieved.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An encapsulant for an electronic package, wherein the encapsulant comprises:
an electrically insulating matrix material; and
stress inhibiting filler particles, having a value of the coefficient of thermal expansion of not more than 6 ppm/K and a value of the Young modulus of not more than 4 GPa, in the matrix material.

2. The encapsulant according to claim 1, wherein the stress inhibiting filler particles have a value of the Young modulus of not more than 1 GPa.

3. The encapsulant according to claim 1, wherein the stress inhibiting filler particles have a value of the coefficient of thermal expansion of not more than 4 ppm/K.

4. The encapsulant according to claim 1, wherein the stress inhibiting filler particles have a negative value of the coefficient of thermal expansion.

5. The encapsulant according to claim 1, wherein the stress inhibiting filler particles are porous.

6. The encapsulant according to claim 5, wherein the stress inhibiting filler particles are closed porous particles.

7. The encapsulant according to claim 5, wherein the porous stress inhibiting filler particles have a ratio between pore volume to whole particle volume in a range from 1% to 40%.

8. The encapsulant according to claim 1, wherein the stress inhibiting filler particles have a functional coating.

9. The encapsulant according to claim 8, wherein the functional coating comprises an adhesion promoter or an insulator.

10. The encapsulant according to claim 9, wherein the adhesion promoter comprises silane or a morphological adhesion promoter.

11. The encapsulant according to claim 1, wherein the stress inhibiting filler particles comprise at least one material of zirconium tungstate, porous silica, boron-silicate glass, β-eucryptite, α-ZrW₂O₈, β-ZrW₂O₈, Cd(CN)₂, ReO₃, (HfMg)(WO₄)₃, Sm_{2.75}C₆₀, Bi_{0.95}La_{0.05}NiO₃, Invar (Fe-36Ni), Invar (Fe₃Pt), Tm₂Fe₁₆Cr, copper oxide nano particles, and Mn₃Cu_{0.53}Ge_{0.47}N.

12. The encapsulant according to claim 1, wherein the stress inhibiting filler particles have a size (D) below 100 μm, in particular in a range from 1 μm to 30 μm.

13. The encapsulant according to claim 1, additionally comprising functional filler particles providing at least one additional function to the encapsulant.

14. The encapsulant according to claim 13, wherein the at least one additional function comprises an increase of thermal conductivity of the encapsulant, an increase of hardness of the encapsulant, and a reduction of mismatch of the coefficient of thermal expansion between the encapsulant and a semiconductor material, in particular silicon or silicon carbide.

15. The encapsulant according to claim 1, wherein the matrix material comprises an epoxy resin, silicone, a bismaleimide or an imide.

16. Encapsulant according to claim 1, comprising at least one of the following features:
configured as a mold compound, in particular as an epoxy-based mold compound;
configured as a potting compound, in particular as an epoxy-based potting.

17. A package, comprising:
a carrier;
an electronic component mounted on the carrier; and
an encapsulant at least partially encapsulating the electronic component and the carrier;
wherein a value of the Young modulus of the encapsulant multiplied with an absolute value of a difference between values of the coefficient of thermal expansion of the encapsulant and of the electronic component is less than 372 GPa*ppm/K.

18. The package according to claim 17, wherein the encapsulant comprises:
an electrically insulating matrix material; and
stress inhibiting filler particles, for example having a value of the coefficient of thermal expansion of not more than 6 ppm/K and/or a value of the Young modulus of not more than 4 GPa, in the matrix material.

19. The package according to claim 17, wherein the encapsulant is according to claim 1.

20. The package according to claim 17, comprising at least one of the following features:
wherein the value of the Young modulus of the encapsulant multiplied with the absolute value of the difference between the values of the coefficient of thermal expansion of the encapsulant and of the electronic component is less than 200 GPa*ppm/K, preferably less than 100 GPa*ppm/K;
wherein the package is a power package;
wherein the electronic component is a semiconductor chip comprising silicon.
